(19) United States
(12) Patent Application Publication
(10) Pub. No.: US 2023/0059594 A1
(43) Pub. Date: Feb. 23, 2023

(54) ENHANCED PROCESS FOR QUBIT FABRICATION

(71) Applicant: International Business Machines Corporation, Armonk, NY (US)

(72) Inventor: Gerald W. Gibson, Danbury, CT (US)

(21) Appl. No.: 17/445,246

(22) Filed: Aug. 17, 2021

(51) Int. Cl. H01L 21/28; H01L 21/02

(52) U.S. Cl. CPC H01L 21/28238; H01L 21/02043; G06N 10/00

(57) ABSTRACT

The method that includes the step of a cleaning a surface of a silicon wafer and forming a sacrificial layer on top of the silicon wafer. The wafer undergoes further processing, wherein the processing includes forming at least one layer directly on top of the sacrificial layer. Immediately prior to the insertion into a dilute refrigeration unit removing a portion of the sacrificial layer by exposing the portion of the sacrificial layer to a solvent.

### STATEMENT REGARDING FEDERALLY FUNDED RESEARCH AND DEVELOPMENT

This invention was made with U.S. Government support. The U.S. Government has certain rights in this invention.

### BACKGROUND

The present invention relates generally to a field of chip manufacturing, and more particularly to a protective layer to prevent defects from forming.

Silicon wafers are commonly used during the manufacturing of qubits. Problems due to a cleanliness of surfaces of the wafer has given arise to multiple problems. Efforts to date have largely addressed the cleaning of exposed surfaces at various points during the qubit fabrication sequence. Multiple cleaning steps are time consuming and can lead to over-etching, unwanted side-products of chemical reactions, and/or residual chemical compounds.

### BRIEF SUMMARY

Additional aspects and/or advantages will be set forth in part in the description which follows and, in part, will be apparent from the description, or may be learned by practice of the invention.

The silicon wafer that includes a sacrificial layer located on the silicon wafer, and at least one layer located on the sacrificial layer, wherein a portion of the at least one layer extends past an edge of the sacrificial layer, and wherein a bottom surface of the at least one layer faces a portion of a top surface of the silicon wafer without material between the surfaces.

The method that includes the step of a cleaning a surface of a silicon wafer and forming a sacrificial layer on top of the silicon wafer. The wafer undergoes further processing, wherein the processing includes forming at least one layer directly on top of the sacrificial layer. Immediately prior to the insertion into a dilute refrigeration unit removing a portion of the sacrificial layer by exposing the portion of the sacrificial layer to a solvent.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 is a top view of an example product, in accordance with the embodiment of the present invention.

FIG. 2 illustrates a cross section of FIG. 1 along the line A-A of the example product, in accordance with the embodiment of the present invention.

FIG. 3 illustrates a cross section of FIG. 1 along line B-B of the example product, in accordance with the embodiment of the invention.

FIG. 4 is a flowchart depicting the method of manufacturing of an example product, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” can be understood to include any integer number greater than or equal to one, i.e. one, two, three, four, etc. The terms “a plurality” can be understood to include any integer number greater than or equal to two, i.e. two, three, four, five, etc. The term “connection” can include both an indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. The terms “about” or “substantially” are intended to include the degree of error associated with measurement of the particular quantity based upon the equipment available at the time of filing application. For example, “about” can include a range of ±8% or 5%, or 2% of a given value. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value. The terms “about” or “substantially” are intended to include the degree of error associated with measurement of the particular quantity based upon the equipment available at the time of filing application.

Various processes used to form a micro-chip that will be packaged into an integrated circuit (IC) fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, wherein like reference numerals refer to like elements throughout. Embodiments of the invention are generally directed to a method of improving substrate cleanliness whereby a substrate is covered by a protective layer which is only removed immediately prior to insertion of the fabricated devices into a dilution refrigerator, thus protecting the substrate from exposure to both process environments and ambient environments during the fabrication sequence. Prior to qubit fabrication, a silicon substrate is carefully cleaned and passivated, then a sacrificial layer of thermal silicon dioxide, titanium, or other appropriate materials is formed on the substrate to create a high quality, buried oxide-silicon interface. A base layer is formed on top of the sacrificial layer, for example, the base layer can be a base electrode, and an electrical component can be formed on the base layer, for example a qubit can be formed on top of the base electrode.

During the fabrication process multiple chips are formed on the single silicon wafer, resulting in dicing the wafer into individual chips prior to operation of the chip. Further, just prior to placing a chip into operation (e.g., placement in the dilution refrigerator), the sacrificial layer covering the silicon substrate is removed using hydrofluoric acid to expose the silicon substrate and terminate its surface with hydrogen bonds, thus passivating it. The acid will remove the silicon dioxide layer beneath a portion of the base electrode, leading to an undercut of the base electrode and will undercut the silicon dioxide layer beneath the electrical component. The net result of this approach is that a nearly pristine, and passivated, substrate surface is placed into the dilution refrigerator, were it is subsequently held under high vacuum. By passivating the surface, and undercutting the qubit located on the sacrificial layer, operation of the qubit may be improved. Specifically, the passivated surface of the silicon wafer helps prevent/minimize formation of oxides on the surface of the substrate, which reduces interference caused by oxides of the substrate on the operation of the qubit. Furthermore, the sacrificial layer does not interfere with the qubit operation since the sacrificial layer is removed from beneath the qubit, and the sacrificial layer can act as an oxide barrier between the silicon wafer and the layer formed directly on top of the sacrificial layer.

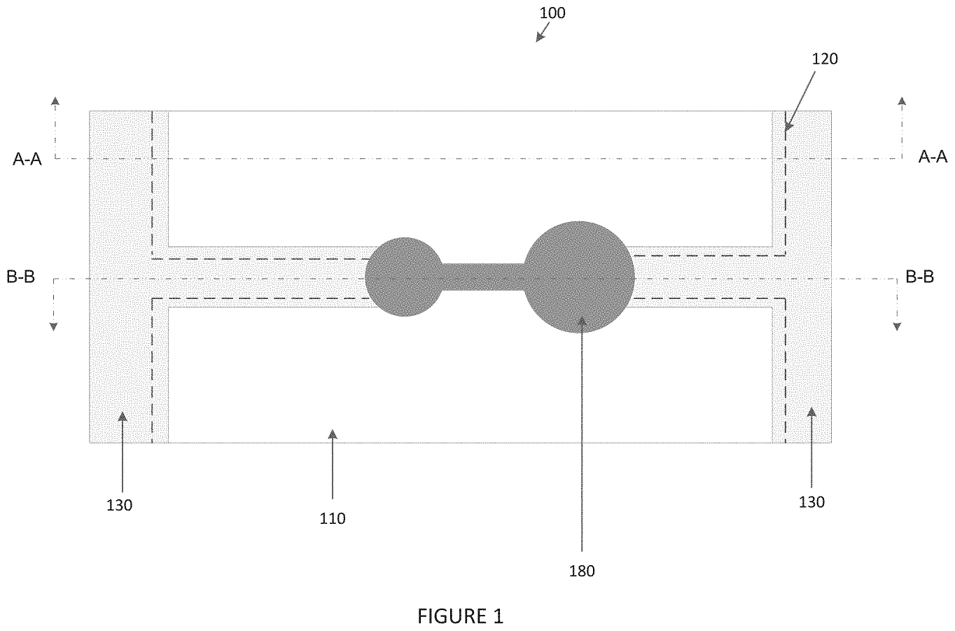

FIG. 1 is a top view of an example product, in accordance with the embodiment of the present invention.

Product 100 is formed from a substrate 110, for example, a silicon wafer 110, which can include, for example, sacrificial layer 122, a base electrode 130, and a connecting layer 180 of an electrical component. The substrate 110 can be, for example, a silicon wafer, a SiGe wafer, a II-IV material, a III-V material, or any type of suitable material to act as a substrate for fabrication of chips. From the top perspective, as illustrated by FIG. 1, the sacrificial layer 122 cannot be seen. However, a undercut edge 120 of the sacrificial layer 122 is indicated as a dashed line, depicting where the undercut edge 120 may be located beneath the first layer 130. The sacrificial layer 122 can be, for example, silicon dioxide, titanium, or other appropriate materials. The use of the base electrode 130 and connecting layer 180 is an example only, one of ordinary skill in the art would realize that any type of layer can be placed on top of the sacrificial layer 122. The material for the base electrode 130 can be any suitable material, however, the use of a base electrode 130 is for example purposes only, any type of appropriate material can be utilized to form the desired layer. The material for the electrical component, where the electrical component can include the tunnel barrier 140, the counter electrode 150, and the connecting layer 180, are not describe within this application, since the formation of these elements on the sacrificial layer 122, are being used as an example only. The base electrode 130 can be, for example, Niobium, the tunnel barrier 140 can be, for example, Al/Aluminum Oxide, the counter electrode 150 can be, for example, Niobium, and the connecting layer 180 can be, for example, Aluminum or Niobium. The previously listed materials are meant to for example purposes only and should not be limiting the scope of the invention. While FIGS. 1-3 show multiple views of an embodiment of a Josephson junction, it should be understood that the technique can apply to other layered structures.

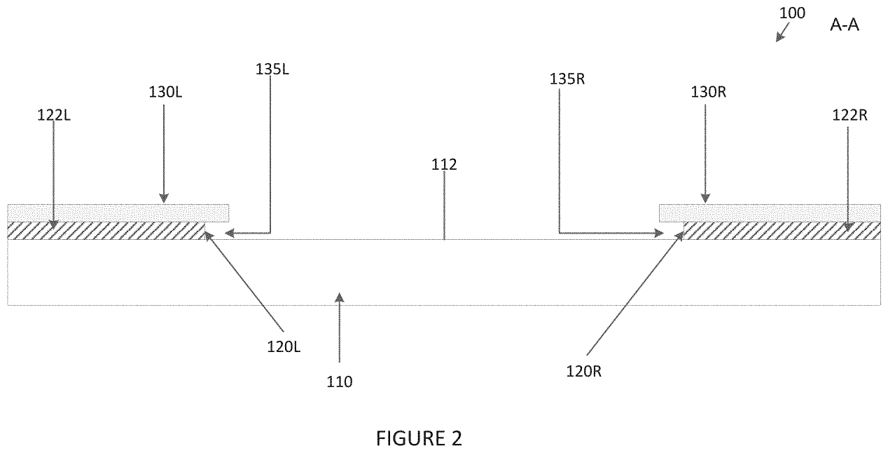

FIG. 2 illustrates a cross sectional view of FIG. 1 along the line A-A of the example product 100, in accordance with the embodiment of the present invention. The product 100 may include the base electrode 130, located on the sacrificial layer 122L and 122R, which is located on the silicon wafer 110. The undercut edge 122L and 122R is beneath the base electrode 130L and 130R, creating an undercut gap 135L and 135R. The undercut gap 135L and 135R is defined by the undercut edge 120L and 120R, the bottom surface of the base electrode 130L and 130R, the top surface of the silicon wafer 110, and the undercut gap 135L and 135R beneath an edge of the base electrode 130L and 130R, respectively. The size of the undercut gap 135L and 135R may be defined by the time, temperature and/or solvent used to perform the selective etching of the sacrificial layer 122. Further, during such etch, a passivated surface 112 is formed on the surface of the silicon wafer 110 as a result of hydrogenation of the surface. The passivated surface 112 prevents oxides or other compounds that might cause an interference from forming, thus improving the electrical qualities of the product 100.

The sacrificial layer 122 tend to harbor two-level systems (TLS) which tend to interfere with an electrical field of some electronic elements. For example, TLS are a contributor to a decoherence of a qubit when the TLS interact with the electrical field of a qubit. By removing the sacrificial layer 122 to create the undercut gap 135L and 135R, the distance of the TLS of the sacrificial layer 122L and 122R from the operating electronic elements is increased, which leads to a reduction in the impact of TLS on the electrical field of the operating electronic elements formed above the sacrificial layer 122.

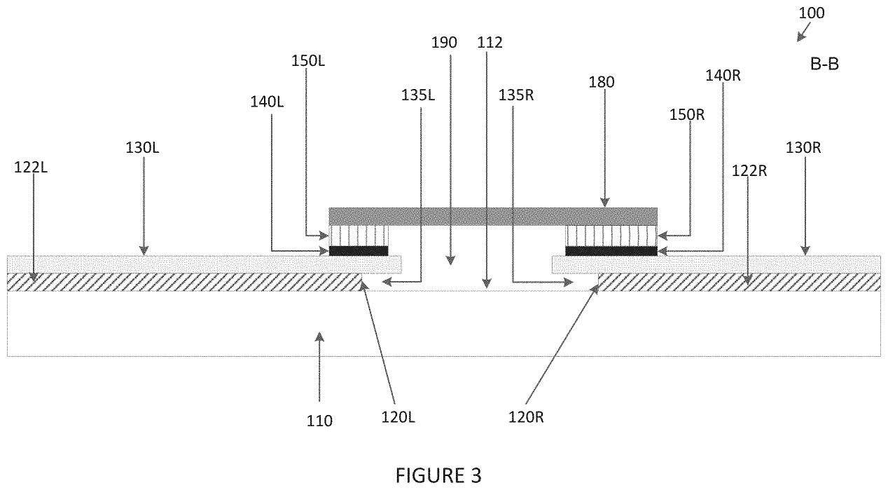

FIG. 3 illustrates a cross sectional view of FIG. 1 along line B-B of the example product 100, in accordance with the embodiment of the invention. The product 100 may include an electrical component including at least a connecting layer 180, located on a counter electrode 150L and 150R, which is located on a tunnel barrier material 140L and 140R, respectively. The tunnel barrier 140L and 140 is located on the base electrode 130L and 130R respectively, located on the sacrificial layer 122L and 122R, respectively, which is located on the silicon wafer 110. The undercut edge 122L is beneath the base electrode 130L, creating an undercut gap 135L. The undercut gap 135L is defined by the undercut edge 120L, the bottom surface of the base electrode 130L, the top surface of the silicon wafer 110, and the undercut gap 135L beneath an edge of the base electrode 130L. The size of the undercut gap 135L may be defined by the time, temperature and/or solvent used to perform the selective etching of the sacrificial layer 122. The undercut gap 135 as illustrated by FIG. 2 is the same undercut gap 135L illustrate by FIG. 3. The undercut edge 122R is beneath the base electrode 130R, creating an undercut gap 135R. The undercut gap 135R is defined by the undercut edge 120R, the bottom surface of the base electrode 130R, the top surface of the silicon wafer 110, and the undercut gap 135R beneath an edge of the base electrode 130R. The size of the undercut gap 135R may be defined by the time, temperature and/or solvent used to perform the selective etching of the sacrificial layer 122. The undercut gap 135L and 135R as illustrated by FIG. 2 is the same undercut gap 135R illustrate by FIG. 3.

The removal of the sacrificial layer 122 beneath the connecting layer 180 creates an empty space 190. The left side of the empty space 190 sides are defined by the counter electrodes 150L, the tunnel barriers 140L, the base electrode 130L, the sacrificial layer 122L, and undercut gap 135L. A right side of the empty space 190 sides are defined by the counter electrodes 150R, the tunnel barriers 140R, the base electrode 130R, the sacrificial layer 122R, and undercut gap 135R. The passivated silicon surface 112 defines the bottom of empty space 190 and the connecting layer 180 defines the top of the empty space 190. The passivated area 112 prevents oxides or other compounds that might cause an interference from forming, thus improving the electrical qualities of the product 100.

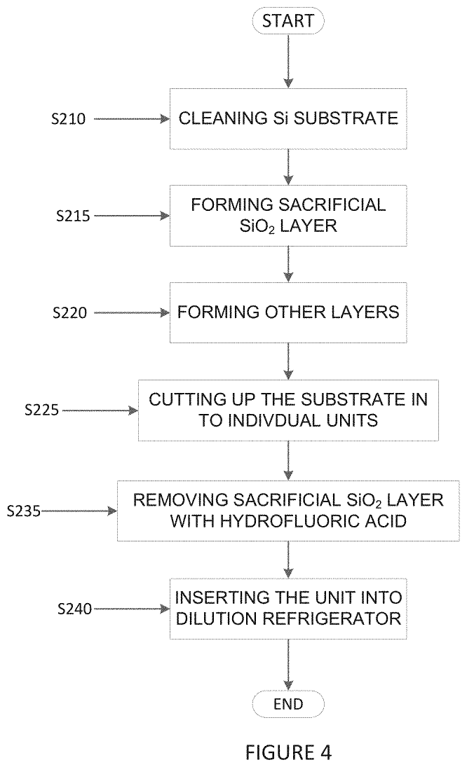

FIG. 4 is a flowchart depicting the method of manufacturing and preparation of an exemplary product for use in a dilution refrigerator, in accordance with the embodiment of the present invention.

A silicon wafer 110 is cleaned and passivated at the start of the manufacturing process (S210). A sacrificial layer 122 of silicon dioxide, titanium, or other material which can be removed selectively to the other materials in the structure, is formed on the surface of the silicon wafer 110 (S215). The sacrificial layer 122 can be formed utilizing different deposition techniques such as, for example, PVD, CVD, ALD or another deposition technique can be utilized in the formation of the sacrificial layer 122. The sacrificial layer 122 acts as a barrier to prevent the formation of unwanted material layers, defects, or other issues on the surface of the silicon wafer 110. The sacrificial layer 122 can be formed by any of the methods describe below. Furthermore, any of the other layers can be deposited, etched, or otherwise formed by the below described procedures.

The electrical component including at least one layer, or a plurality of layers, may be formed on top of the sacrificial layer 122 (S220). The electrical component can be formed utilizing different deposition techniques, for example, PVD, CVD, ALD, as well as patterning and removal of unwanted portions of the layer, to form the electrical component. The at least one layer can be formed directly on top of the sacrificial layer 122 (S220). An electrical component can be formed on the at least one layer that is located on top of the sacrificial layer 122 (S220). Multiple versions of product 100 may be formed at the same time on the silicon wafer 110. The multiple versions of products 100 may be diced into an individual product 100 that will be placed within a dilute refrigeration unit (S225).

An amount of the sacrificial layer 122 that is removed is dependent on the exposure time of the sacrificial layer 122 to a solvent such as, for example, hydrofluoric acid. The amount of the sacrificial layer 122 removed will determine how much an undercut gap 135 is formed. Prior to the product 100 insertion into a dilute refrigeration unit, the product 110 is exposed a solvent, for example, hydrofluoric acid, to remove a portion of the sacrificial layer 122 to create the undercut beneath the layer that is directly on top of the sacrificial layer 122 (S235). Further, during the undercut of the sacrificial layer beneath the base electrode 130 the hydrofluoric acid terminates the surface of silicon wafer 110 with hydrogen bonds, thus passivating it. Following removal of the sacrificial layer 122, the product 100 may be placed into the dilute refrigeration unit (S240).

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. An apparatus comprising:
a silicon wafer;
a sacrificial layer located on said silicon wafer; and
at least one layer located on the sacrificial layer, wherein a portion of the at least one layer extends past an edge of the sacrificial layer, and wherein a bottom surface of the at least one layer faces a portion of a top surface of the silicon wafer without material between the surfaces.

2. The apparatus of claim 1, wherein a material of said sacrificial layer comprises a material selected from a group consisting of: silicon dioxide and titanium.

3. The apparatus of claim 1, further comprising:
at least one electrical component is located on top of said at least one layer.

4. The apparatus of claim 3, wherein the at least one electrical component is formed from one additional layer.

5. The apparatus of claim 3 wherein the at least one electrical component is formed from a plurality of different layers.

6. The apparatus of claim 1, further comprising:
a passivated surface of silicon located on the portion of the top surface of said silicon wafer.

7. A method comprising:
cleaning a surface of a silicon wafer;
forming a sacrificial layer on top of said silicon wafer;
processing the silicon wafer, wherein the processing includes forming at least one layer directly on top of the sacrificial layer; and
prior to the insertion into a dilute refrigeration unit removing a portion of the sacrificial layer by exposing the portion of the sacrificial layer to a solvent.

8. The method of claim 7, wherein a material of said sacrificial layer comprises a material selected from a group consisting of: silicon dioxide and titanium.

9. The method of claim 8, wherein said solvent comprises hydrofluoric acid.

10. The method of claim 7, wherein said portion of the sacrificial layer that was removed causes some of the at least one layer extends past an edge of the sacrificial layer, and wherein a bottom surface of the at least one layer faces a portion of a top surface of the silicon wafer without material between the surfaces.

11. The method of claim 7, wherein the amount of the removed portion of said sacrificial layer is determined based on the time the sacrificial layer is exposed to the solvent.

12. The method of claim 7, further comprising:
forming a passivated surface of silicon located at the area on said silicon wafer where the sacrificial layer was removed.

13. The method of claim 7, further comprising:
during the processing of said silicon wafer forming additional layers on the surface of the at least one layer.

14. The method of claim 7 wherein a plurality of units is formed on said silicon wafer during the process stage, when the process of the silicon wafer is finished, cutting the silicon wafer so that the plurality of units is separated into individual units, wherein only one individual unit is exposed to the solvent at a time immediately prior to insertion of the individual unit into the dilute refrigeration unit.

15. An apparatus comprising:
a first sacrificial layer located on a first portion of a substrate;
a first base electrode, wherein first portion of said first base electrode is located directly on the first sacrificial layer and wherein a second portion of the first base electrode does not have any material from the sacrificial layer between the first base electrode and the substrate;
a first tunnel barrier located on the second portion of the first base electrode;
a second sacrificial layer located on a second portion of a substrate;
a second base electrode, wherein a first portion of the second base electrode is located directly on the second sacrificial layer and wherein a second portion of the second base electrode does not have any material from the sacrificial layer between the second base electrode and the substrate; and
a second tunnel barrier located the top of the second base electrode;
a connecting layer electrically connecting the first tunnel barrier to the second tunnel barrier.

16. The apparatus of claim 15, wherein a material of said sacrificial layer comprises a material selected from a group consisting of: silicon dioxide and titanium.

17. The apparatus of claim 15, further comprising:
a passivated surface of silicon located on the portion of the top surface of said silicon wafer.
